(19) United States
(12) Patent Application Publication
(10) Pub. No.: US 2012/0120608 A1
(43) Pub. Date: May 17, 2012

(54) PRINTED CIRCUIT BOARD WITH HEAT SINK

(75) Inventor: ZHI-BIN GUAN, Tu-Cheng (TW)

(73) Assignee: HON HAI PRECISION INDUSTRY CO., LTD., Tu-Cheng (TW)

(21) Appl. No.: 12/949,785

(22) Filed: Nov. 19, 2010

(30) Foreign Application Priority Data
Nov. 11, 2010 (TW) 99138893

(51) Int. Cl. H05K 7/20

(52) U.S. Cl. 361/704

(57) ABSTRACT

A printed circuit board includes a heat sink and a circuit board. The heat sink includes four magnetic poles extending from four corners of a bottom of the heat sink. The circuit board includes a heat-generating component and four magnetic holders corresponding to the magnetic poles. Each magnetic holder defines an inserting hole to receive a corresponding magnetic pole. The heat sink is fixed on the circuit board and the heat-generating component contacts to the bottom of the heat sink in response to the magnetic poles being inserted into the inserting holes of the magnetic holders.

### BACKGROUND

1. Technical Field

The present disclosure relates to a printed circuit board including a heat sink.

2. Description of Related Art

Finned heat sinks have been found to be particularly effective for transferring heat through conduction from a heat-generating component such as a semiconductor chip and rapidly dissipating such heat into the environment. For fixing the heat sink on the heat-generating component, a common method is to use a rotating element to fix the heat sink. However, the rotating element needs to extend through a channel between two adjacent fins of the heat sink, which may influence heat dissipation effect.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawing, all the views are schematic, and like reference numerals designate corresponding parts throughout the several views.

FIG. 1 is an exploded, isometric view of an embodiment of a printed circuit board including a heat sink.

FIG. 2 is similar to FIG. 1, but viewed from another perspective.

FIG. 3 is an assembled, isometric view of the printed circuit board of FIG. 1.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

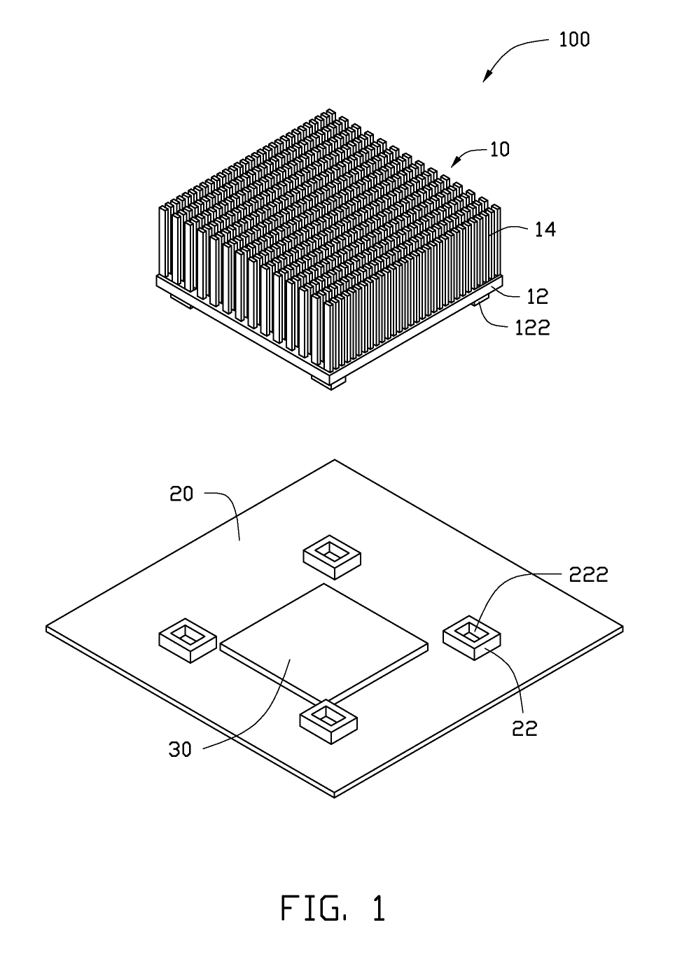

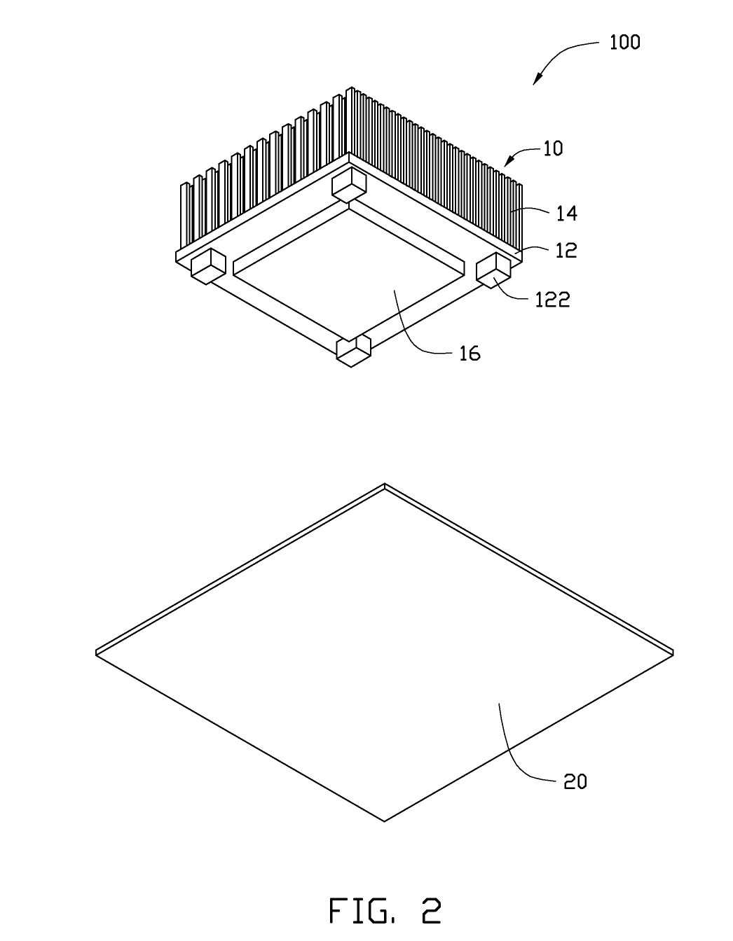

Referring to FIGS. 1 and 2, an embodiment of a printed circuit board 100 includes a heat sink 10 and a circuit board 20.

The heat sink 10 includes a rectangular thermal-conductive base 12 and a number of thermal-conductive fins 14 protruding substantially perpendicularly from a top of the base 12. A substantially rectangular conducting board 16 extends from a bottom of the base 12. Four rectangular magnetic poles 122 extend from four corners of the bottom of the base 12. The magnetic poles 122 are made of strong permanent magnet. In other embodiments, the shape of the magnetic poles 122 can be other shapes, such as cylinders.

The circuit board 20 includes a heat-generating component 30 and four magnetic holders 22 around the component 30 corresponding to the magnetic poles 122. The size of the component 30 is substantially equal to the size of the conducting board 16. In other embodiments, if the component 30 is very thick, the conducting board 16 cannot be used. Each holder 22 defines a rectangular inserting hole 222, which can receive a corresponding magnetic pole 122. The holders 22 are made of magnetic material.

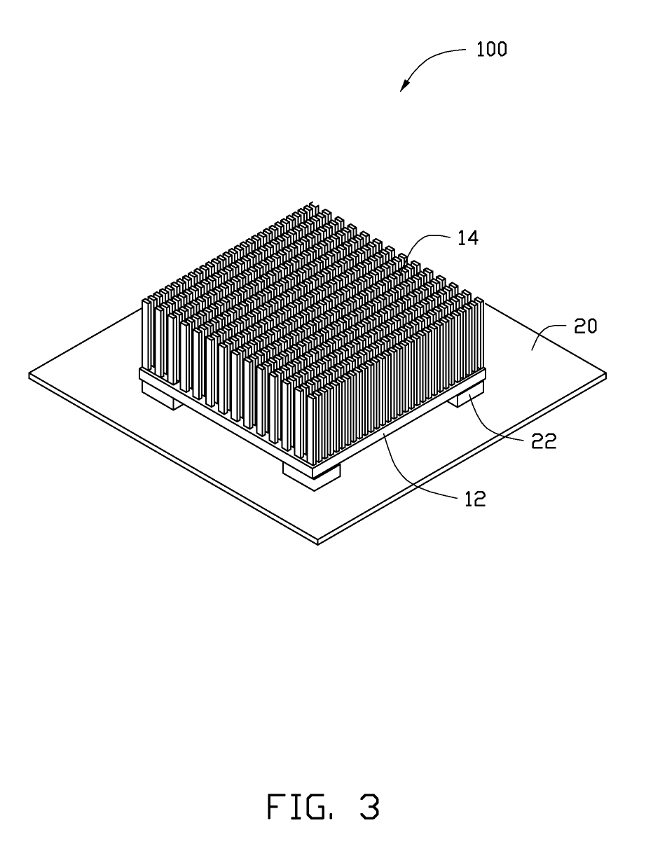

Referring to FIG. 3, in assembly, the magnetic poles 122 are inserted into the corresponding inserting holes 222 of the holders 22. At this time, the conducting board 16 contacts tightly to the component 30. The compressive stress between the conducting board 16 and the component 30 can be adjusted by selecting a proper magnetic intensity of the magnetic poles 122, to satisfy heat dissipation requirements. Therefore, the heat sink 10 is fixed on the heat-generating component 30 quickly. The magnetic poles 122 do not need to extend through the fins 14 of the heat sink 10, which can increase heat dissipation effect of the heat sink 10.

It is to be understood, however, that even though numerous characteristics and advantages of the embodiments have been set forth in the foregoing description, together with details of the structure and function of the embodiments, the disclosure is illustrative only, and changes may be made in details, especially in matters of shape, size, and arrangement of parts within the principles of the embodiments to the full extent indicated by the broad general meaning of the terms in which the appended claims are expressed.

What is claimed is:

1. A printed circuit board comprising:
a heat sink comprising four magnetic poles extending from four corners of a bottom of the heat sink; and
a circuit board comprising a heat-generating component and four magnetic holders corresponding to the magnetic poles, wherein each magnetic holder defines an inserting hole to receive a corresponding magnetic pole;
wherein the heat sink is fixed on the circuit board and the heat-generating component contacts to the bottom of the heat sink in response to the magnetic poles being inserted into the inserting holes of the magnetic holders.

2. The printed circuit board of claim 1, wherein the heat sink further comprises a conducting board extending from the bottom of the heat sink, a size of the conducting board is substantially equal to a size of the heat-generating component, the heat-generating component contacts to the conducting board in response to the magnetic poles being inserted into the inserting holes of the magnetic holders.

3. The printed circuit board of claim 1, wherein the magnetic poles are substantially rectangular.

4. The printed circuit board of claim 1, wherein the magnetic poles are made of permanent magnet, the magnetic holders are made of magnetic material.

5. A printed circuit board comprising:
a heat sink comprising a plurality of magnetic poles extending from a bottom of the heat sink; and
a circuit board comprising a heat-generating component and a plurality of magnetic holders corresponding to the plurality of magnetic poles, wherein each magnetic holder defines an inserting hole to receive a corresponding magnetic pole;
wherein the heat sink is fixed on the circuit board and the heat-generating component contacts to the bottom of the heat sink in response to the magnetic poles being inserted into the inserting holes of the magnetic holders.

6. The printed circuit board of claim 5, wherein the heat sink further comprises a conducting board extending from the bottom of the heat sink, a size of the conducting board is substantially equal to a size of the heat-generating component, the heat-generating component contacts to the conducting board in response to the magnetic poles being inserted into the inserting holes of the magnetic holders.

7. The printed circuit board of claim 5, wherein the magnetic poles are substantially rectangular.

8. The printed circuit board of claim 5, wherein the magnetic poles are made of permanent magnet, the magnetic holders are made of magnetic material.
